(19) United States
(12) Patent Application Publication
(10) Pub. No.: US 2008/0315251 A1
(43) Pub. Date: Dec. 25, 2008

(54) SEMICONDUCTOR DEVICE AND METHOD FOR FABRICATING THEREOF

(76) Inventor: Sang-Yong Lee, Bucheon-si (KR)

Correspondence Address: SHERR & VAUGHN, PLLC, 620 HERNDON PARKWAY, SUITE 200, HERNDON, VA, 20170, US

(21) Appl. No.: 12/142,916

(22) Filed: Jun. 20, 2008

(30) Foreign Application Priority Data
Jun. 20, 2007 (KR) 10-2007-0060520

(51) Int. Cl. H01L 29/739; H01L 21/331

(52) U.S. Cl. 257/141; 438/135; 257/E29.197; 257/E21.382

(57) ABSTRACT

A semiconductor device and/or a method for fabricating a semiconductor device (e.g. fabricating an LIGBT) that may minimize occurrences of latch-up due to increases of hole current. A semiconductor device and/or a method of fabricating a semiconductor device that may prevent and/or eliminate latch-up due to operation of a parasitic thyrister without significantly deteriorating performances of significant parameters considered when fabricating a high voltage power control device.

The present application claims priority under 35 U.S.C. 119 to Korean Patent Application No. 10-2007-0060520 (filed on Jun. 20, 2007), which is hereby incorporated by reference in its entirety.

### BACKGROUND

Embodiments relate to semiconductor device fabrication. Embodiments relate to a lateral insulated gate bipolar transistor (LIGBT), which may be a power semiconductor device and/or a method of fabricating a LIGBT.

Examples of power control devices that may control voltage-current are power MOSFETs, BJTs, insulated gate bipolar transistors (IGBT), gate turn-off thyristors (GTO), emitter switched thyrister (EST), and/or other similar devices. System-on-chips is technology that my implement an entire system (or many components of a system) on a single chip. It may be desirable for power devices to have logic circuitry and power control devices on a single chip. However, in order to couple power control devices together with logic circuit, it may be desirable to use lateral device. Lateral device may be structured to have an electrode is positioned on an upper portion of a wafer. Examples of lateral devices are LIGBTs, LDMOSFETs, and/or LESTs.

When LIGBTs are used as the power control devices, it may be desirable that the area occupied by that power device is minimized. Since LIGBTs are devices that combine advantages of bipolar transistors and MOSFETs, LIGBTs may have excellent forward characteristic compared to power MOSFET devices.

When fabricating power control devices (e.g. high voltage power control devices), breakdown-voltage, on-resistance, saturation current, and/or device size are design factors. When fabricating high voltage power devices, compromise and adjustment between parameters may be made. For example, if parameters relating to breakdown-voltage are increased, parameter relating to on-resistance may be decreased. For example, if the current capacity of a device is increased, latch-up may easily be generated by a parasitic thyristor (e.g. a thyristor generated due to the structural of a device that is independent of the design).

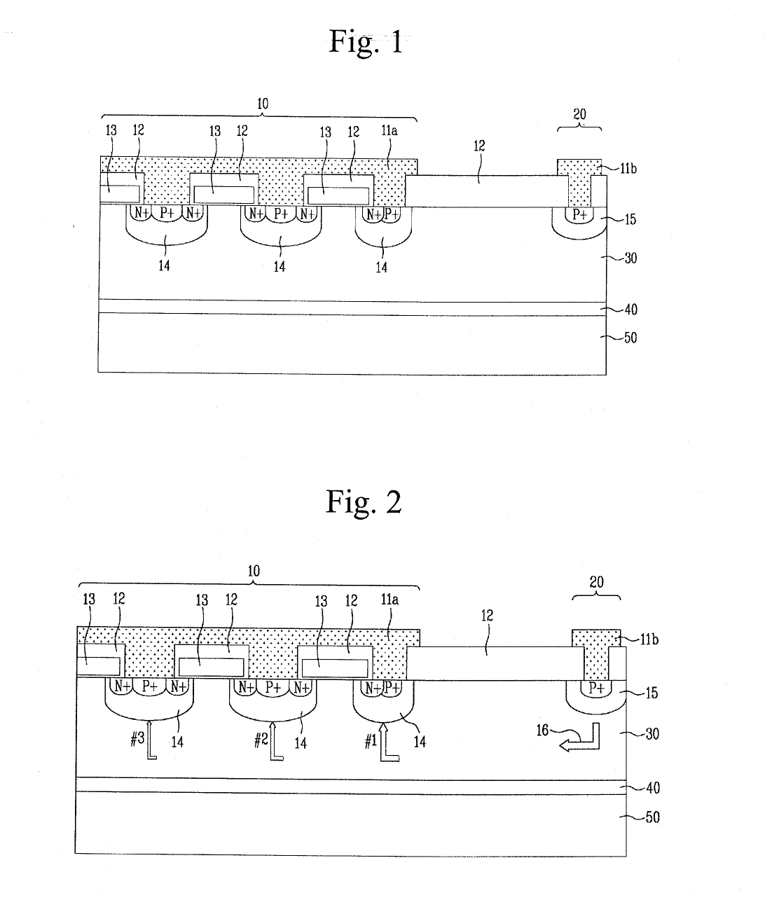

Example FIG. 1 is a cross-sectional view illustrating a structure of a LIGBT. Semiconductor substrate 50, buried oxide 40, and N-drift layer 30 may be sequentially stacked to form a wafer. The inside of the wafer may be formed with a plurality of impurity diffusion regions. Emitter electrode 11a may be formed in emitter region 10. Emitter region 10 may include a plurality of impurity diffusion regions forming an N+/P+ junction and an N+/P+/N+ junction in a P-base 14. A metal electrode (e.g. emitter electrode 11a and gate electrode 13) may be formed on and/or over the impurity diffusion regions. Emitter electrode 11a and gate electrode 13 may be spaced by gate insulating layer 12.

Collector region 20 may include collector electrode 11b. Collector region 20 may include an impurity diffusion region forming a P+ junction in N-buffer 15. A metal electrode (e.g. collector electrode 11a) may be formed on and/or over the impurity diffusion region in the collector region 20. Emitter electrode 11a and collector electrode 11b may be spaced by gate insulating layer 12.

A lower P-base surrounding the junctions may have a certain level of resistance, which may relate to latch-up. For example, as a gate voltage becomes high during operation, the collector voltage may increase; as the collector voltage becomes high, the current level may increase so that a larger current flows to emitter region 10. When a hole current generated in the collector increases, a voltage drop may occur between N+ and the P-base by resistance of P-base in emitter region 10. Accordingly, a parasitic thyristor having a four-layer (P-N-P-N) structure may operate. Due to operation of a parasitic thyristor, an on/off switching function of the device (e.g. based on the gate voltage level) may be compromised or inoperable. Excess current because of inoperable on/off switching may cause breakdown of the device.

Example FIG. 2 is a view illustrating flow of hole current in a LIGBT structure. Hole current 16 may be generated in collector region 20, which may be concentrated in impurity diffusion region #1 closest to collector electrode 11b. Hole current 17 may be generated due to resistance of N-drift layer 30 and may be distributed to remaining impurity diffusion regions #2 and #3 in inverse proportion to the distance from collector electrode 11b.

Since hole current 16 that may generate at collector region 20 may be concentrated in impurity diffusion region #1 (closest to the collector electrode 11b) and also distributed to impurity diffusion regions #2 and #3, there may be complication of increased latch-up occuring in impurity diffusion region #1 closest to the collector electrode 11b.

### SUMMARY

Embodiments relate a semiconductor device and/or a method for fabricating a semiconductor device (e.g. fabricating an LIGBT) that minimizes occurrences of latch-up due to increases of hole current. Embodiments relate to a semiconductor device and/or a method of fabricating a semiconductor device that prevents and/or eliminates latch-up due to operation of a parasitic thyrister without significantly deteriorating performances of significant parameters considered when fabricating a high voltage power control device.

In embodiments, a semiconductor device includes at least one of the following: A wafer. A first electrode region including a P-type junction in an N-buffer formed in the wafer. A second electrode including a first impurity diffusion region (e.g. including an NP type junction in a first P-base formed in the wafer) and a second impurity diffusion region (e.g. including a deep P-type junction in a second P-base formed in the wafer).

In embodiments, a wafer may include a semiconductor substrate and an N-drift layer formed in an upper portion of the semiconductor substrate. The wafer may include a buried oxide formed between the semiconductor substrate and the N-drift layer, in accordance with embodiments. In embodiments, the semiconductor device may include a collector electrode formed in an upper portion of the first electrode region.

In embodiments, a semiconductor device may include an emitter electrode and a gate electrode formed to be spaced by an insulating layer on an upper portion of the second electrode region. For example, a deep P-type junction may be formed in a second P-base to connect the emitter electrode and the N-drift layer in the wafer. In embodiments, the first P-base and the second P-base may have approximately the same depth in the wafer. In embodiments, the second P-base may have a narrower width than the first P-base. In embodiments, the deep P-type junction may have a narrower width than the second P-base and a greater depth than the second P-base. In embodiments, the second impurity diffusion region may be closest to the first electrode region.

Embodiments relate to a method of fabricating a semiconductor device that includes at least one of the following steps: Forming a N-drift layer in a semiconductor substrate. Forming a P-base in the N-drift layer. Forming a P-type junction in the P-base. Forming a deep P-type junction injected up to the N-drift layer in the P-type junction. Forming a metal electrode on and/or over the deep P-type junction.

Embodiments related to a method of fabricating a semiconductor device that includes at least one of the following steps: Forming a wafer. Forming P-bases in each of a first impurity diffusion region and a second impurity diffusion region defined in the wafer. Forming an NP-type junction in the P-base of the first impurity diffusion region and forming a P-junction in the P-base of the second impurity diffusion region. Forming a deep P-type junction injected up to the wafer in the P-type junction formed in the second impurity diffusion region. Forming metal electrodes on and/or over the NP-type junctions formed in the first impurity diffusion region and the deep P-type junction formed in the second diffusion region.

In embodiments, the P-base of the first impurity diffusion region and the P-base of the second impurity diffusion region have approximately the same depth in the wafer. In embodiments, the P-base of the first impurity diffusion region and the P-base of the second impurity diffusion region may have different widths. In embodiments, the P-base of the second impurity diffusion region may be formed to have a narrower width than the P-base of the first impurity diffusion region. In embodiments, the deep P type junction may be formed by being injected up to a depth deeper than the P-base formed in the second impurity diffusion region and have a narrower width than the P-type junction formed in the second impurity diffusion region.

In embodiments, the deep P-type junction may be formed by being injected up to a depth deeper than the P-base formed in the second impurity diffusion region and have a width narrower than the P-base formed in the second impurity diffusion region. In embodiments, the second impurity diffusion region of the first impurity diffusion region and the second impurity diffusion region may be formed to be closest to an electrode emitting electrons. In embodiments, the forming of the wafer includes forming an N-drift layer in an upper portion of the semiconductor substrate. In embodiments, the forming of the wafer includes forming a buried oxide in an upper portion of a semiconductor substrate and forming an N-drift layer in an upper portion of the buried oxide.

### DRAWINGS

Example FIG. 1 is a cross-sectional view illustrating a LIGBT structure.

Example FIG. 2 is a view illustrating flow of hole current in a LIGBT structure.

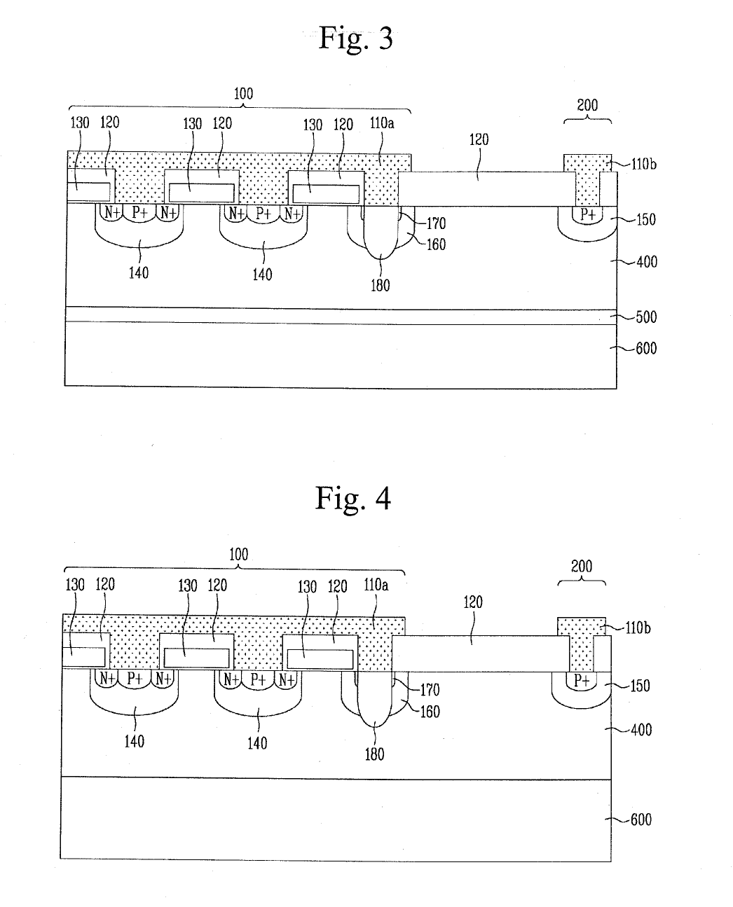

Example FIG. 3 is a cross-sectional view illustrating a LIGBT structure, in accordance with embodiments.

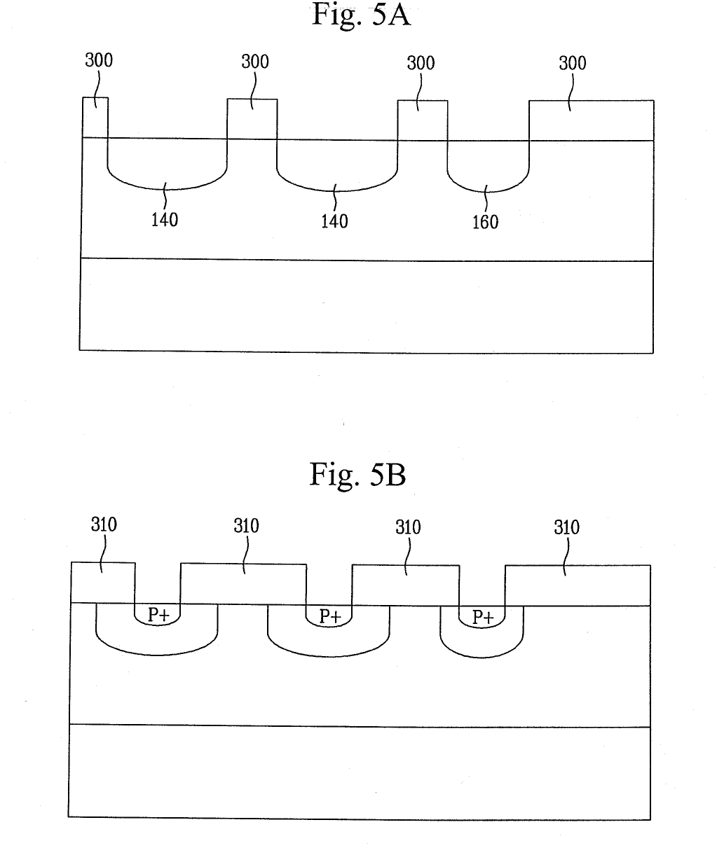

Example FIG. 4 is a cross-sectional view illustrating a LIGBT structure, in accordance with embodiments.

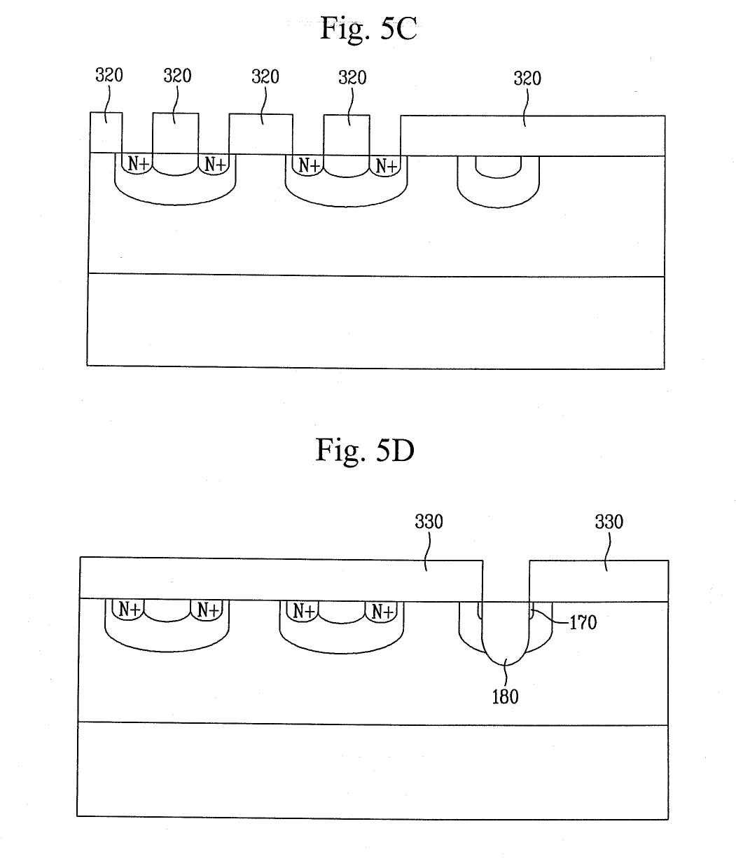

Example FIGS. 5A to 5D illustrate a process of fabricating a LIGBT, in accordance with embodiments.

### DESCRIPTION

Example FIG. 3 is a cross-sectional view illustrating a LIGBT structure, in accordance with embodiments. Example FIG. 4 is a cross-sectional view illustrating a LIGBT structure, in accordance with embodiments.

Example FIG. 3 illustrates an example using a silicon-on-insulator (SOI) wafer including semiconductor substrate 600, buried oxide 500, and/or N-drift layer 400, which may be sequentially stacked, in accordance with embodiments. Example FIG. 4 illustrates an example using a wafer including semiconductor substrate 600 and/or N-drift layer 400, which may be sequentially stacked, in accordance with embodiments.

In the SOI wafer illustrated in FIG. 3, buried oxide 500 may be formed on and/or over semiconductor substrate 600, in accordance with embodiments. N drift layer 400 may be formed by ion implanting N type impurities on and/or over buried oxide 500. For example, after depositing an oxide on and/or over semiconductor substrate 600 and then forming a silicon layer, N type impurities may be ion implanted on and/or over the silicon layer.

In the wafer of FIG. 4, for example, after forming the silicon layer on the upper of the semiconductor 600, N-drift layer 400 may be formed by ion implanting N type impurities on the silicon layer, in accordance with embodiments. A wafer having N-drift layer 400 may include collector region 200, a first electrode region, and emitter region 100 (e.g. a second electrode region). In embodiments, several impurity diffusion regions may be present in the wafer in emitter region 100.

In embodiment, first impurity diffusion region may include a NP type junction (N+/P+/N+) in P-base 140 and a second impurity diffusion region including deep P type junction 180 in P-base 160. A NP type junction (N+/P+/N+) of a first impurity diffusion region may have a structure that it is surrounded by P-base 140, in accordance with embodiments. A deep P type junction of a second impurity diffusion region may have a structure that it is surrounded by P-base 160, in accordance with embodiments. In embodiments, a second impurity diffusion region may have an impurity diffusion region that is closest to collector region 200. P-base 140 of a first impurity diffusion and P-base 160 of a second impurity diffusion region may be formed at approximately the same depth in the wafer, in accordance with embodiments. P-base 160 of a second impurity diffusion region may have a narrower width narrower than P-base 140 of a first impurity diffusion region, in accordance with embodiments.

In embodiments, an impurity diffusion region may exist in collector region 200 in the wafer. A collector region may include a P type junction (P+) in N-buffer 150. Collector region 200 may include a metal electrode (collector electrode) 110b formed on and/or over an impurity diffusion region and may be electrically coupled to the impurity diffusion region. In embodiments, P-base 140, P-base 160 and/or N-buffer 150 may have a well structure.

Emitter region 100 may include a metal electrode (emitter electrode) 110a formed on and/or over impurity diffusion regions, which may be electrically connected to the impurity diffusion regions and gate electrode 130. Emitter electrode 110a and gate electrode 130 may be electrically isolated from each other by insulating material. For example, emitter electrode 110a and gate electrode 130 may be spaced by a gate insulating layer.

Deep P type junction 180 may be formed in P-base 160 of a second impurity diffusion region and may be coupled to emitter electrode 110a. A NP type junction (N+/P+/N+) may be coupled emitter electrode 110a. In embodiment, a portion of emitter electrode 110a may overlap with N+s on both sides.

Gate electrode 130 may be formed on and/or over a channel region that is between two adjacent impurity diffusion regions. In embodiments, gate electrode 130 may be formed to at least partially overlap with two impurity diffusion regions. In embodiments, the overlapped portions of gate electrode 130 are spaced by a predetermined amount. Deep P type junction 180 may be coupled to emitter electrode 110a. Deep P type junction 180 may be formed in an upper portion of the wafer and may be coupled to N-drift layer 400 in the wafer.

In embodiments, deep P type junction 180 may have a width narrower than P-base 160 of the second impurity diffusion region. Deep P type junction 180 may have a greater depth than P-base 160 in the wafer. Deep P type junction 180 may be coupled to N-drift layer 400 in the wafer.

In embodiments, the width of deep P type junction 180 may be narrower than P type junction 170 formed in P-base 160. P type junction 170 may be formed prior to formation of deep P type junction 180. Deep P type junction 180 may be formed by forming P-base 160 of second impurity diffusion region, forming the P type junction 170 in P base 160, and then forming deep P type junction 180 by diffusion to form deep P type junction 180 that penetrates through P-base 160. In embodiments, deep P type junction 180 may penetrate below P-base 160.

In embodiments, deep P type junction 180 may be formed instead of a NP type junction. Deep P type junction 180 may be formed in a second impurity diffusion region that is closest to collector region 200. In embodiments, deep P type junction 180 may significantly minimize resistance of P-base 160 against current flow to the emitter region 100. Due to minimization of resistance of P-base 160, in embodiments, hole current flowing from collector region 200 may be concentrated at P type junction 180.

Example FIGS. 5A to 5D are views illustrating a process of fabricating a LIGBT, in accordance with embodiments. In embodiments, a process forms a plurality of impurity diffusion regions in emitter region 100.

In embodiments, a wafer is first formed. The formed wafer may have an N-drift layer. As illustrated in FIG. 5A, P-base 140 and P-base 160 may formed in a N-drift layer using mask pattern 300, in accordance with embodiments. P-base 140 and P-base 160 may be formed in a well structure. P-base 140 and P-base 160 may be formed by implanting ions and then diffusing the ions. In embodiments, P-base 160 may be formed on a side that is closest to collector region 200 (to be formed in a subsequent stop). Collector region 200 may be a region including a collector electrode emitting electrons.

An impurity diffusion region including P-base 160 may be referred to as a second impurity region, while an impurity diffusion region including P-bases 140 may be referred to as a first impurity diffusion region. P-base 140 of a first impurity diffusion region and P-base 160 of a second impurity diffusion region may be formed to have substantially the same depth in the wafer. In embodiments, P-base 140 and P-base 160 may be formed to have different widths. In embodiments, P-base 160 may be formed to have a width more narrow than P-base 140, as illustrated in FIG. 5A.

In embodiments, P type impurities may be ion implanted in the wafer using mask pattern 310 to form P type junctions in P-bases 140 and P-base 160, as illustrated in FIG. 5B. In embodiments, N type impurities may be ion implanted in the wafer using mask pattern 320 to form an N type junctions in the P-bases 140, as illustrated in FIG. 5C. N type junctions may not be formed in P-base 160 through selectivity of mask pattern 320, in accordance with embodiments. N type junctions may be formed in the vicinity of previously formed P type junctions to form NP type junctions (N+/P+/N+) in P-bases 140.

In embodiments, P type impurities may be ion implanted in the wafer using mask pattern 330 to form deep P type junction 180 in P-base 160, as illustrated in FIG. 5D. Ions may be implanted deeper than P-base 160 and into the N-drift layer. In embodiments, mask pattern 330 may be formed to be more narrow than the width of mask pattern 310. Accordingly, in embodiment, a portion 170 of the P type junction formed in the second impurity diffusion region may remain at both sides of deep P type junction 180.

In embodiments, deep P type junction 180 may be formed so that portion 170 of the P type junction does not remain at both sides of the deep P type junction 180. For example, mask pattern 310 may be configured so that a P type junction is not formed in a second impurity diffusion region (e.g. mask pattern 310 selectively masks the region where deep P type junction 180 will be formed).

In embodiments, metal electrodes may be formed on and/or over the wafer. For example, a gate electrode and an emitter electrode may be sequentially formed on and/or over first impurity diffusion region and/or second impurity diffusion region.

In embodiments, a deep P type junction may formed in an emitter region instead of a NP type junction in an impurity diffusion region closest to a collector region. In embodiments, resistance may be significantly minimized in a P-base against current flowing to an emitter region, which may minimize occurrences of latch-up due to increases of hole current. In embodiments, a LIGBT may be used, which may minimize latch-up generated by operation of a parasitic thyrister without deteriorating performances of parameters considered in fabricating a high voltage power control device.

In embodiments, a LIGBT structure may be useful in implementing a device having a large current capacity without deteriorating the performances of parameters considered in fabricating a high voltage power device. In embodiments, since a LIGBT structure may maximize tolerance for latch-up generated by operation of a parasitic thyrister (even at high currents), embodiments may be useful in implementing a high voltage device and/or a high current device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a wafer;
a first electrode region comprising a P-type junction in an N-buffer, wherein the P-type junction and the N-buffer are formed in the wafer; and
a second electrode comprising a first impurity diffusion region and a second impurity diffusion region, wherein:
the first impurity diffusion region comprising an NP-type junction formed in a first P-base formed in the wafer, and
the second impurity diffusion region comprising a deep P-type junction in a second P-base formed in the wafer.

2. The apparatus of claim 1, wherein the wafer comprises:
a semiconductor substrate; and
an N-drift layer formed in an upper portion of the semiconductor substrate.

3. The apparatus of claim 2, wherein the wafer comprises a buried oxide formed between the semiconductor substrate and the N-drift layer.

4. The apparatus of claim 1, wherein the first electrode region comprises a collector electrode formed over at least one of the P-type junction and the N-buffer.

5. The apparatus of claim 1, wherein:
the second electrode region comprises an emitter electrode and a gate electrode;
the emitter electrode and the gate electrode are spaced by an insulating layer; and
the emitter electrode and the gate electrode are formed over at least one of the first impurity diffusion region and the second impurity diffusion region.

6. The apparatus of claim 5, wherein:
the deep P-type junction is at least partially formed in the second P-base; and
the deep P-type junction couples the emitter electrode and the N-drift layer in the wafer.

7. The apparatus of claim 1, wherein the first P-base and the second P-base have approximately the same depth in the wafer.

8. The apparatus of claim 1, wherein the second P-base has a width less than the width of the first P-base.

9. The apparatus of claim 1, wherein:
the deep P-type junction has a width less than the width of the second P-base; and
the deep P-type junction has a depth greater than the depth of the second P-base.

10. The apparatus of claim 1, wherein the second impurity diffusion region is adjacent to the first electrode region.

11. A method comprising:
forming an N-drift layer over a semiconductor substrate;
forming a P-base in the N-drift layer;
forming a P-type junction in the P-base;
forming a deep P-type junction by injection through the N-drift layer in the P-type junction; and
forming a metal electrode over the deep P-type junction.

12. A method comprising:
forming a wafer;
forming a plurality of first P-bases in a first impurity diffusion region in the wafer;
forming at least one second P-base in a second impurity diffusion region in the wafer;
forming at least one NP-type junction in at least one of the first P-bases;
forming at least one P-junction in said at least one second P-base;
forming at least one deep P-type junction by injection the P-junction; and
forming metal electrodes over said at least one NP-type junction and said at least one deep P-type junction.

13. The method of claim 12, wherein at least one of said plurality of first P-bases and said at least one second P-base have approximately the same depth in the wafer.

14. The method of claim 12, wherein at least one of said plurality of first P-bases and said at least one second P-base have different widths.

15. The method of claim 12, wherein the said at least one second P-base has a width less than at least one of said plurality of first P-bases.

16. The method of claim 12, wherein:
the deep P type junction is formed by injection to a depth deeper than said at least one second P-base; and
the deep P type junction has a width less than said at least one P-type junction.

17. The method of claim 12, wherein:
the deep P-type junction is formed by injection at a depth deeper than said at least one second P-base; and
the deep P-type junction has width less than said at least one second P-base.

18. The method of claim 12, wherein the second impurity diffusion region is adjacent to an electrode emitting electrons.

19. The method of claim 12, wherein said forming the wafer comprises forming an N-drift layer over a semiconductor substrate.

20. The method of claim 12, wherein said forming the wafer comprises:
forming a buried oxide over a semiconductor substrate; and
forming an N-drift layer over the buried oxide.
